(19) United States
(12) Patent Application Publication
(10) Pub. No.: US 2018/0173346 A1
(43) Pub. Date: Jun. 21, 2018

(54) TOUCH SENSOR AND TOUCH DISPLAY PANEL

(71) Applicant: SHANGHAI TIANMA MICRO-ELECTRONICS CO., LTD., SHANGHAI (CN)

(72) Inventors: Lingxiao DU, SHANGHAI (CN); Kang YANG, SHANGHAI (CN); Hong DING, SHANGHAI (CN)

(73) Assignee: SHANGHAI TIANMA MICRO-ELECTRONICS CO., LTD., SHANGHAI (CN)

(21) Appl. No.: 15/894,928

(22) Filed: Feb. 13, 2018

(30) Foreign Application Priority Data
Sep. 27, 2017 (CN) 201710889072.X

(51) Int. Cl. G06F 3/044; H01L 27/12; G06F 3/041

(52) U.S. Cl. CPC G06F 3/044; G06F 3/0412; H01L 27/1214

(57) ABSTRACT

A Touch sensor and a touch display panel, including a plurality of first electrodes and second electrodes respectively extending in a first direction and a second direction, the first electrode is insulated from and intersects with the second electrode, a first leading wire connected with first electrode connects the first electrode to bonding pin, a second leading wire connected with second electrode connects the second electrode to bonding pin, the first electrode and first leading wire are respectively disposed in the first and second conductive layer, the first electrode is connected to first leading wire via an insulation layer through hole disposed between the first and second conductive layer, the first electrode and the first leading wire are disposed in different layers, the first leading wire and the second leading wire are led out from a side of the touch detection area close to the bonding pin.

### CROSS-REFERENCE TO RELATED APPLICATIONS

The present application claims priority to Chinese Patent Application No. 201710889072.X, filed on Sep. 27, 2017, the content of which is incorporated herein by reference in its entirety.

### TECHNICAL FIELD

The present disclosure relates to the field of touch screens and, in particular, to a touch sensor and a touch display panel.

### BACKGROUND

As an input medium, a touch screen is the most simple, convenient and natural way of human-computer interaction at present. Integrating a touch function on a display device has become a research hotspot for more and more flat-panel display manufacturers.

A projected capacitive touch screen, due to its multi-finger touch function, has become the most common touch screen at present. According to the detection principle, a capacitive touch screen may be classified as a self-capacitance screen and a mutual-capacitance screen. The self-capacitance screen sequentially detects horizontal and vertical electrode arrays, respectively, and according to the change of the capacitance before and after the touch, horizontal coordinates and the vertical coordinates are respectively determined and then are combined to form plane touch coordinates. As for the mutual-capacitance screen, a capacitor is formed at the intersection between a horizontal electrode array and a vertical electrode array, that is, the two groups of electrodes constitute two electrodes of the capacitor. When a finger touches the capacitance screen, the coupling between the two electrodes nearby the touch point is influenced, thereby changing the capacitance between the two electrodes. Regardless of the self-capacitance screen or the mutual capacitance screen, the horizontal and the vertical electrodes may need to be connected with an end of an integration circuit via the electrode leading wire, respectively. Since the horizontal electrode arrays are led from two ends, and routed via the left and right sides of the horizontal electrodes, thus increasing the size of the touch screen border at both left and right ends, which is a disadvantage for designing a narrow border.

### SUMMARY

The present disclosure provides a touch sensor and a touch display panel with a narrow border.

In one aspect, the present disclosure provides a touch sensor, the touch sensor has a touch detection area and a peripheral area, and the touch sensor includes: a first conductive layer including a plurality of first electrodes extending in a first direction; a second conductive layer including a plurality of first leading wires; an insulation layer disposed between the first conductive layer and the second conductive layer; a plurality of second electrodes extending in a second direction, the second electrodes being disposed in the first conductive layer or the second conductive layer, the first electrodes being insulated from the second electrodes; a plurality of bonding pins disposed in the peripheral area external to a side of the touch detection area in the second direction; a plurality of second leading wires; and an angle is formed between the first direction and the second direction, which is neither equal to 0 degree nor equal to 180 degrees; each first leading wire has two ends, one end of each first leading wire is electrically connected with a respective one of the plurality of first electrodes, and the other end of each first leading wire is electrically connected with a respective one of the plurality of bonding pins, one end of each second leading wire is electrically connected with a respective one of the plurality of second electrodes, and the other end of each second leading wire is electrically connected with a respective one of the plurality of bonding pins; the insulation layer includes a plurality of first through holes, and each first leading wire is electrically connected with the respective first electrode via a respective one of the plurality of first through holes; the plurality of first leading wires and the plurality of second leading wires are led out from a side of the touch detection area close to the bonding pin.

In another aspect, the present disclosure provides a touch display panel including the above-mentioned touch sensor,

The touch sensor and touch display panel provided by the present disclosure have one or more of the following advantages: a plurality of first electrodes and second electrodes respectively extend in a first direction and a second direction, the first electrode is insulated from and intersects with the second electrode, a first leading wire connected with the first electrode electrically connects the first electrode with the bonding pin, a second leading wire connected with the second electrode electrically connects the second electrode with the bonding pin, the first electrode and the first leading wire are respectively disposed in the first conductive layer and the second conductive layer, the first electrode is connected with the first leading wire via an insulation layer through hole disposed between the first conductive layer and the second conductive layer, by setting the first electrode and the first leading wire to be disposed in different layers, so that the first leading wire may not need to be led out from two ends of the first electrode, both the first leading wire and the second leading wire are led out from a side of the touch detection area close to the bonding pin, so that the first leading wire and the second leading wire only exist at one side of the peripheral area where the bonding pin is located, thereby decreasing the border of the touch sensor.

### BRIEF DESCRIPTION OF DRAWINGS

FIG. 1 is a schematic diagram of a touch sensor provided by an embodiment of the present disclosure;

FIG. 2 is a cross-sectional view along AB in FIG. 1;

FIG. 3 is a schematic diagram of a second conductive layer of the touch sensor shown in FIG. 1;

FIG. 4 is a schematic diagram of a first conductive layer of the touch sensor shown in FIG. 1;

FIG. 5 is a schematic diagram of another touch sensor provided by an embodiment of the present disclosure;

FIG. 6 is a cross-sectional view along CD in FIG. 5;

FIG. 7 is a cross-sectional view along EF in FIG. 5;

FIG. 8 is a cross-sectional view along GH in FIG. 5;

FIG. 9 is a schematic diagram of a touch display panel provided by an embodiment of the present disclosure;

FIG. 10 is a schematic diagram of another touch display panel provided by an embodiment of the present disclosure; and

FIG. 11 is a schematic diagram of still another touch display panel provided by an embodiment of the present disclosure.

### DESCRIPTION OF EMBODIMENTS

Since the above-mentioned technology involves in various changes and implementation manners, the detailed implementation manners will be shown in the accompanying drawings and described in detail in the written description. The effects and features of the described technology will now be described more fully with reference to the accompanying drawings, in which exemplary embodiments are shown. However, the above-mentioned technology may be implemented in many different manners and should not be construed as limited to the embodiments herein.

The same or corresponding elements are denoted by the same reference numbers and are not related to the figure numbers, and in the description, the expressions such as “first”, “second”, etc., may be used to describe various elements but these elements are not limited to the above expressions. The above expressions are merely used to distinguish one element from another.

In the specification, the expression “comprising” or “including” is used to specify the presence of the features and/or elements described in the specification, without excluding the presence of one or more other feature and/or one or more other element. It should be understood that, when a layer, an area, an element, etc., is referred to as being “on/at/in” another layer, another area, or another element, then it can be directly on/at/in the other layer, area, or element, or, it is also possible that there is an intermediate layer, an intermediate area or an intermediate element.

In the accompanying drawings, the thickness of the layer and/or the area is exaggerated for clarity. For example, for the sake of description, the thickness and size of the element are arbitrarily shown in the accompanying drawings, therefore, the described technical scope is not limited by the accompanying drawings.

Hereinafter, in one or more exemplary embodiment, an axis X, an axis Y, and an axis Z may not be limited to three axes in a rectangular coordinate system, but may be construed as a broad meaning of three axes. For example, an axis X, an axis Y, and an axis Z may be perpendicular to each other or may represent different directions that are not perpendicular to each other.

In addition, it should be noted that, in some alternative implementation manners, the steps of all the methods described herein may not occur in order. For example, two steps shown as sequential steps may be performed substantially simultaneously, or the two steps may sometimes be performed in a reverse order.

As used herein, the expression “and/or” includes any and all combinations of one or more of the associated listed items. When the expression such as “at least one of ” is disposed after an element list, it indicates the entire element list rather than an individual element of the list. in the present disclosure, the expression “substantially” includes the meaning of completeness, almost completeness or any significant degree under some applications or according to those skilled in the art. In addition, the expression “formed, arranged or placed on top of ” may also mean “formed, arranged or placed on . . . ”. The expression “connection” includes the meaning of “electrical connection”.

For more clarity, the same reference numbers are used for the same structures in different accompanying drawings.

The present disclosure will be described in detail with reference to the accompanying drawings in the following.

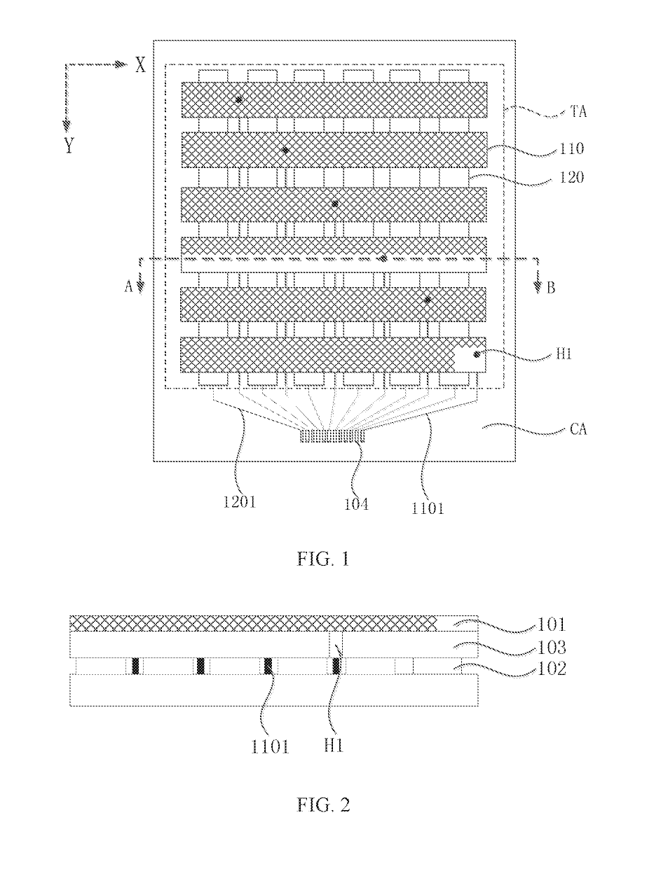

FIG. 1 is a schematic diagram of a touch sensor provided by an embodiment of the present disclosure. FIG. 2 is a cross-sectional view along AB in FIG. 1. As shown in FIG. 1 and FIG. 2, the touch sensor includes a touch detection area TA and a peripheral area CA. The touch sensor further includes a first conductive layer 101 and a second conductive layer 102, and an insulation layer 103 disposed between the first conductive layer 101 and the second conductive layer 102. The first conductive layer 101 includes a plurality of first electrodes 110 extending along a first direction X. The touch sensor further includes a plurality of second electrodes 120 extending along a second direction Y, and an angle is formed between the first direction X and the second direction Y, which is neither equal to 0 degree nor equal to 180 degrees. The second electrodes 120 are disposed at the first conductive layer or at the second conductive layer. It is taken as an example that the second electrodes 120 are disposed at the second conductive layer 102 in FIG. 2. The first electrodes 110 are insulated from the second electrodes 120. The touch sensor further includes a plurality of bonding pins 104 disposed in the peripheral area external to a side of the touch detection area in the second direction. The second conductive layer 102 includes a plurality of first leading wires 1101, one end of the first leading wire 1101 being electrically connected with one of the first electrodes 110, and the other end of the first leading wire 1101 being electrically connected with the bonding pin 104.

The touch sensor further includes a plurality of second leading wires 1201, one end of the second leading wire 1201 being electrically connected with one of the second electrodes 120, and the other end of the second leading wire 1201 being electrically connected with the bonding pin 104.

The insulation layer 103 includes a plurality of first through holes H1, the first leading wire 1101 being electrically connected with the first electrode 110 via the first through hole H1.

The first leading wire 1101 and the second leading wire 1201 are led out from a side of the touch detection area TA close to the bonding pin 104.

The touch sensor in the present disclosure can achieve a function of touch position detection, and the function of touch detection can be achieved by mutual-capacitance touch-control or by self-capacitance touch-control.

As for the mutual-capacitance touch-control, a touch drive electrode and a touch detection electrode are applied. The touch drive electrode is sequentially input with a touch drive signal, and the touch detection electrode outputs a detection signal. The touch drive electrode and the touch detection electrode form a capacitor. When a touch occurs, the coupling between the touch drive electrode and the touch detection electrode nearby the touch point may be influenced, thereby changing the capacitance between the touch drive electrode and the touch detection electrode. A method for detecting the position of the touch point is that, sequentially inputting a touch drive signal to the touch drive electrode, meanwhile outputting a touch detection signal by the touch detection electrode, so as to obtain capacitance values of all of the intersections at which touch drive electrodes intersect with touch detection electrodes, that is, the capacitance values of the entire two-dimensional plane. Based on two-dimensional capacitance variation data, the coordinate of a touch point can be achieved.

As for the self-capacitance touch-control, a touch drive signal is input to a touch electrode, and a capacitor is formed between the touch electrode and a ground. When a touch occurs, the self-capacitance between the touch electrode nearby the touch point and the ground may change, meanwhile the touch electrode outputs a touch detection signal, so that the touch electrode position where the capacitance value changes then can be obtained, and thus the touch position can be determined. The touch detection mode in the embodiments of the present disclosure may be a mutual-capacitance touch-control or a self-capacitance touch-control.

The touch sensor includes: a touch detection area TA, which is an area capable of detecting a touch position; and a peripheral area CA, which is generally used for setting a leading wire and a bonding pin, and is bound to a flexible circuit board. In an embodiment, the peripheral area CA is at least disposed at a side of the touch detection area TA in the second direction Y, and a plurality of bonding pins 104 is disposed in the peripheral area CA and used for being bound with the flexible circuit board.

The touch sensor includes a first conductive layer 101, a second conductive layer 102 and an insulation layer 103 between the first conductive layer and the second conductive layer. The first conductive layer and the second conductive layer may be made of any suitable conductive material, such as tin indium oxide, nano-silver, carbon nanotube, metal mesh, etc. The material of the first conductive layer and the material of the second conductive layer may be either the same or different. The insulation layer 103 may be made of any suitable insulation material, for example, it may be an inorganic insulation layer, e.g. made of such as silicon oxide, silicon nitride, silicon oxynitride and the like, or it may be an organic insulation layer.

The first conductive layer 101 includes a plurality of first electrodes 110. The first electrodes 110 may be strip-like electrodes extending along a first direction X, that is, the first electrodes 110 are made by the first conductive layer 101. And the touch sensor further includes a plurality of second electrodes 120. The second electrodes 120 extend along a second direction Y. An angle is formed between the first direction X and the second direction Y, which is neither equal to 0 degree nor equal to 180 degrees. In one embodiment, the first direction X is perpendicular to the second direction Y. The second electrodes 120 may be made by the first conductive layer 101 or by the second conductive layer 102. The first electrodes 110 keep being insulated from the second electrodes 120 no matter which conductive layer the second electrodes 120 are disposed in. Herein, the first electrodes and the second electrodes together form touch electrodes of the touch sensor. When the touch sensor is a self-capacitance touch sensor, both the first electrode 110 and the second electrode 120 are self-capacitance electrodes. When the touch sensor is a mutual-capacitance touch sensor, the first electrode 110 and the second electrode 120 are respectively a touch drive electrode and a touch detection electrode of a mutual-capacitance touch. Regardless of the self-capacitance touch or the mutual-capacitance touch, both the first electrode and the second electrode need to be electrically connected with the bonding pin via a leading wire. By binding the bonding pin 104 to the flexible circuit board, the input and output of touch signal can be achieved. In the embodiments, the bonding pin 104 is disposed in the peripheral area external to a side of the touch detection area TA in the second direction Y.

The first electrode 110 is electrically connected with the bonding pin 104 via the first leading wire 1101, the first leading wire 1101 being made by the second conductive layer. That is, the first electrode 110 and the first leading wire 1101 are disposed in different conductive layers. In order to achieve the electrical connection between the first electrode 110 and the first leading wire 1101, the insulation layer 103 includes a plurality of first through holes H1, and the first leading wire 1101 is electrically connected with the first electrode 110 via the first through hole H1.

The second electrode 120 is electrically connected with the bonding pin 104 via the second leading wire 1201. However, the lamination relationship between the second leading wire 1201 and the second electrode 120 is not limited by the embodiments.

In an embodiment, the first leading wire 1101 and the second leading wire 1201 are led out from a side of the touch detection area TA close to the bonding pin 104. Since the second electrodes 120 extend along the second direction Y, the second leading wire 1201 may be electrically connected with an end of the second electrode 120 close to the bonding pin 104 in the extending direction of the second electrode 120, and thus the second leading wire 1201 can directly enter the peripheral area from an end of the second electrode 120 so as to be electrically connected with the bonding pin 104. As for the first electrode and the first leading wire, an extending direction of the first electrodes 110 is the first direction. The first leading wire 1101 and the first electrode 110 are electrically connected via the first through hole H1, and all the first through holes H1 are disposed in the touch detection area. In this case, the first leading wire 1101 is disposed in the touch detection area. The extending direction of the first leading wire 1101 in the touch detection area may be the second direction, and the first leading wire 1101 is directly led out from the side of the touch detection area close to the bonding pin 104, in this case, the first leading wire is only disposed in the touch detection area and the peripheral area having pins. In this embodiment, the first leading wire and the first electrode are disposed in different layers. Both the first leading wire and the second. leading wire are led out from the side of the touch detection area close to the bonding pin, so as to achieve a narrow border of the touch sensor.

In one embodiment, FIG. 3 is a schematic diagram of a second conductive layer of the touch sensor shown in FIG. 1. As shown in FIG. 3, the second electrodes 120 are still disposed at the second conductive layer, and the second electrodes 120 are strip-like electrodes extending along the second direction. There is a gap between adjacent second electrodes, the first leading wire 1101 is disposed between adjacent second electrodes 120, and an extending direction of the first leading wire 1101 in the touch detection area TA is a second direction Y. In the embodiments of the present disclosure, optionally, the material of the first conductive layer and the second conductive layer is metal mesh, which is a mesh formed by a plurality of metal lines intersecting with each other and electrically connected with each other. Different from a first conductive layer and/or a second conductive layer made of transparent conductive material (transparent metal oxide such as tin indium oxide), when the material of both the first conductive layer and the second conductive layer is metal mesh, the material of the portion of the first leading wire in the touch detection area TA may be the same as the material of the second electrode, that is, the portion of the first leading wire 1101 in the touch detection area TA is also made of metal mesh. It should be understood that, as for a technical solution in which the material of the first conductive layer and the second conductive layer is transparent conductive material, the first leading wire is disposed in the second conductive layer, and the first leading wire is made of transparent conductive material. Since the transparent conductive material such as tin indium oxide has a relatively high resistance value, and has worse ductility compared with metal, this technical solution is difficult to be applied practically, the first leading wire made of the transparent conductive material has an excessively large impedance and is easily disconnected as a long wire. In addition, the second electrode disposed at the second conductive layer is made of transparent conductive material, the first leading wire is disposed at the second conductive layer, and it is difficult to additionally manufacture the first leading wire using metal, which is not technically feasible.

In an embodiment, both the first conductive layer and the second conductive layer are made of metal mesh, and the first leading wire is also formed using metal mesh. On one hand, the first leading wire can be formed together with the second electrode in one process, without needing to manufacture the first leading wire separately, and on the other hand, the impedance of the first leading wire with the metal mesh is substantially decreased. Due to the crossed mesh arrangement, the impedance of the first leading wire is even smaller than that of the related art using a metal line as the touch leading wire, greatly improving the accuracy of touch detection. And as for the related art in which the touch leading wire is disposed at the left and right sides of the bonding pin in the border, it is difficult to use metal mesh as the material of the leading wire, because the metal mesh touch wiring is wider than the metal wire and occupies a larger area of the border, which is a disadvantage for designing the narrow border of the touch sensor.

In an embodiment of the present disclosure, the first leading wire 1101 is lead out from one side of the touch detection area close to the bonding pin, the portion of the first leading wire 1101 within the peripheral area and the second leading wire are disposed in the same layer, the portion of the first leading wire 1101 within the peripheral area and the second leading wire are may have the same material, i.e., both non-mesh wires, which can decrease the area of the peripheral area having the bonding pin and decrease the bottom border of the touch sensor.

With reference to FIG. 3, a plurality of second electrodes extending along the second direction are disposed at the second conductive layer, a dummy electrode 150 is further disposed between adjacent second electrodes, and the dummy electrode 150 has a floating potential. Since the first leading wire 1101 is disposed between adjacent second electrodes 120, when the first electrode 110 and the second electrode 120 respectively act as a touch drive electrode and a touch detection electrode of a mutual-capacitance touch detection, the second electrode 120 and the first leading wire 1101 respectively have different touch signals (touch drive signal and touch detection signal). Since the dummy electrode 150 has a floating potential, the dummy electrode 150 is capable of isolating the signal interference between the second electrode 120 and the first leading wire 1101. In addition, the dummy electrode 150 can decrease the load of the second electrode 120. In one embodiment, with reference to FIG. 3, there is a dummy electrode 150 between the portion of the first leading wire 1101 within the touch detection area TA and the adjacent second electrode 120. The dummy electrode 150 may be strip-like and extends in the second direction. The strip-like dummy electrode 150 can completely isolate the signal interference between the first leading wire 1101 and the second electrode 120, thereby improving the sensitivity of touch detection.

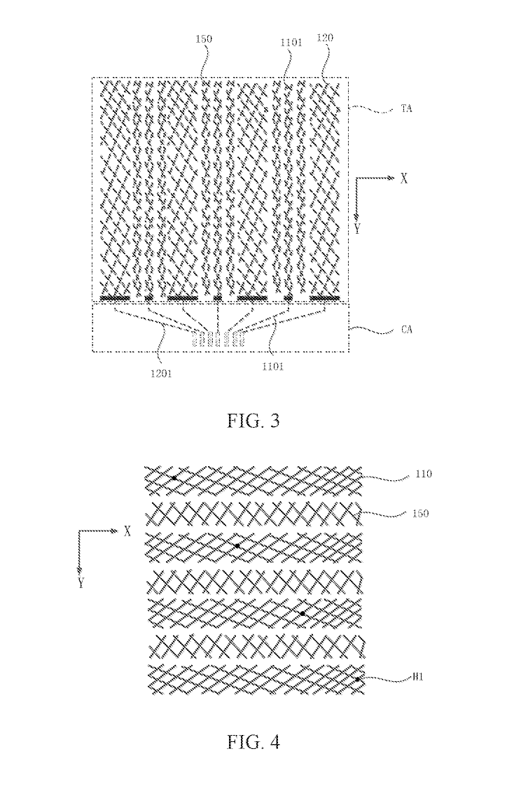

FIG. 4 is a schematic diagram of a first conductive layer of the touch sensor shown in FIG. 1. As shown in FIG. 4, a plurality of first electrodes 110 extending in the first direction is provided in the first conductive layer, and a dummy electrode 150 is further disposed between adjacent first electrodes 110. The dummy electrode 150 can decrease the load of the first electrode 110. When the dummy electrodes 150 are respectively disposed between adjacent first electrodes 110 in the first conductive layer and between adjacent second electrodes 120 in the second conductive layer, the optical uniformity of the touch sensor can be improved. It should be noted that, for clearly showing the first electrode 110, the second electrode 120, the dummy electrode 150 and the first leading wire 1101, the patterns of the metal mesh in FIG. 3 and in FIG. 4 are distinguished, however, this is not limitation to the embodiments. The actual mesh patterns, densities of the first electrode 110, the second electrodes 120, the dummy electrodes 150 and the first leading wires 1101 may be completely the same, which may be more beneficial to optical uniformity.

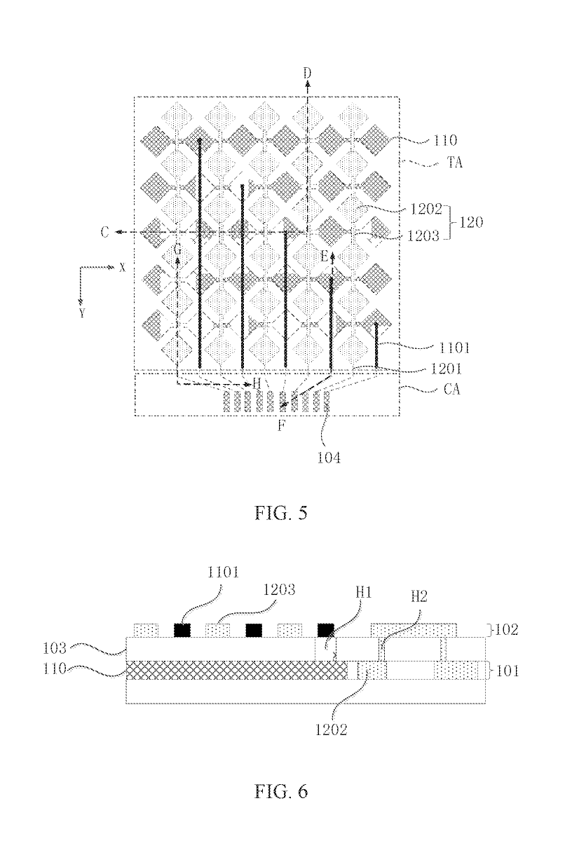

FIG. 5 is a schematic diagram of another touch sensor provided by an embodiment of the present disclosure, and FIG. 6 is a cross-sectional view along CD in FIG. 5. As shown in FIG. 5 and FIG. 6, the second electrode 120 is disposed in the first conductive layer 101, the second electrode 120 includes a plurality of second sub-electrodes 1202, there is a bridging metal 1203 between adjacent second sub-electrodes 1202, and the bridging metal 1203 is disposed in the second conductive layer 102.

The insulation layer 103 includes a plurality of second through holes H2, and the bridging metal 1203 electrically connects the second sub-electrodes 1202 via the second through hole H2.

In an embodiment, both the first electrode 110 and the second electrode 120 are disposed in the first conductive layer 101, the first electrodes 110 extend in the first direction X, the second sub-electrodes 1202 form the second electrode 120 via the bridging metal 1203 disposed in the second conductive layer, and the second electrodes 120 extend in the second direction Y. In an embodiment, the material of the first conductive layer may be tin indium oxide, nano-silver, carbon nanotube, metal mesh, etc., and the material of the second conductive layer may be metal or metal mesh. As shown in FIG. 5, multiple bridging metals electrically connecting multiple second sub-electrodes 1202 of the same one second electrode 120 are arranged and extend in the second direction Y, and the first leading wire 1101 electrically connected with the first electrode 110 is disposed between bridging metals 1203 of two adjacent second electrodes. The portion of the first leading wire 1101 within the touch detection area extends in the second direction Y, so that the first leading wire 1101 is directly led out from the side of the touch detection area close to the bonding pin 104. The first leading wire 1101 and the bridging metal 1203 of the second electrode may both be metal mesh. A dummy electrode may be disposed in an area of the second conductive layer excluding the area where the first leading wire and the bridging metal of the second electrode are disposed. The dummy electrode, on one hand, decreases the load of the first leading wire, on the other hand, balances the optical property of the touch sensor. In one embodiment, the second leading wire 1201 and the bridging metal may be disposed in the same layer, that is, disposed at the second conductive layer. The second leading wire and the second electrode may be connected via a through hole, or the second leading wire is electrically connected with the bridging metal connected to the second sub-electrodes.

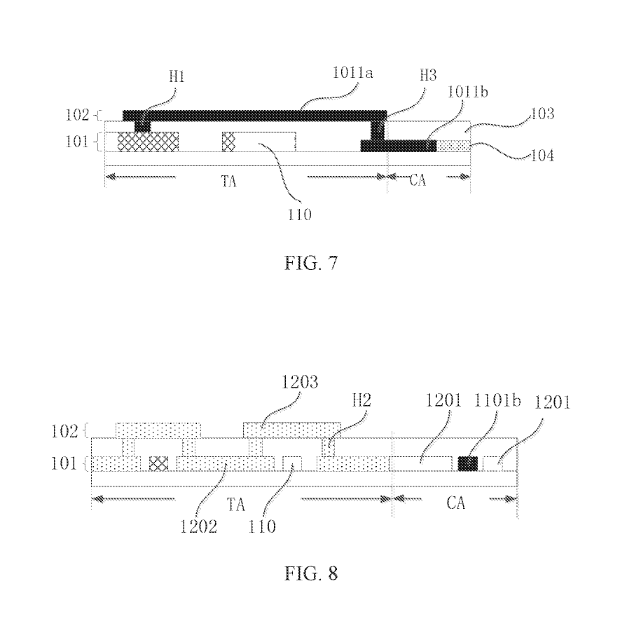

FIG. 7 is a sectional view along EF in FIG. 5, and FIG. 8 is a cross-sectional view along GH in FIG. 5. With reference to FIGS. 5, 7 and 8, the first leading wire 1101 includes a first section 1101a and a second section 1101b. The first section 1101a is disposed in the touch detection area TA and disposed in the second conductive layer. The second section 1101b is disposed in the peripheral area and disposed in the first conductive layer. The first section 1101a is electrically connected with the second section 1101b via a third through hole H3 of the insulation layer 103. The third through hole H3 is disposed at the end of the touch detection area TA close to the bonding pin 104. In an embodiment, both the first electrode 110 and the second electrode 120 are disposed in the first conductive layer. The second leading wire 1201 electrically connected with the second electrode 120 may be disposed in the first conductive layer. The second leading wire 1201 may be electrically connected with an end of the second electrode 120 close to the bonding pin 104 in the extending direction of the second electrode 120, so that the second leading wire 1201 can directly enter the peripheral area from an end of the second electrode 120 so as to be electrically connected with the bonding pin 104. The first section 1101a. of the first leading wire 1101 disposed in the touch detection area is disposed in the second conductive layer and electrically connected with the first electrode 110 via the first through hole H1. When the first section 1101a is led out front an end of the touch detection area close to the bonding pin 104 and is electrically connected with the second section 1101b disposed in the first conductive layer via the third through hole H3, the second section 1101b may be formed together with the second leading wire 1201 in the same one process, and the second section 1101b together with the second leading wire 1201 may be connected with the bonding pin 104, so as to simplify the manufacturing process while decreasing binding difficulty between the bonding pin and the flexible circuit hoard. Optionally, the material of the second leading wire may be metal, that is, the second leading wire 1201 is a non-mesh metal wire, and the material of the first section 1101a of the first leading wire is metal mesh. The material of the second section 1101b is the same as the material of the second leading wire, that is, the second section 1101b is a non-mesh metal wire. With the first section 1101a of the first leading wire being metal mesh, the resistance of the first leading wire may be decreased and the accuracy of touch detection may be improved. With the second section 1101b being a non-mesh metal wire, the area of the peripheral area having the bonding pin may be decreased and the lower border of the touch sensor may be decreased.

As for the touch sensor provided by the embodiments of the present disclosure, by setting the first leading wire and the first electrode in different layers, the left and right borders at two sides of the area where the bonding pin of the touch sensor is disposed can be decreased. On the other hand, the first leading wire is disposed in the second conductive layer, the second conductive layer is provided with the second electrode or the bridging metal of the second electrode, and an additional conductive layer may not be needed for the first leading wire, so that the thickness of the touch sensor is decreased while the process difficulty is also decreased. In addition, the second conductive layer can be made of metal mesh material, in this case, both the second electrode and the portion of the first leading wire disposed in the touch detection area are metal mesh material, which can greatly decrease the resistance of the first leading wire, meanwhile the second electrode made of the metal mesh has better flexibility and lower impedance.

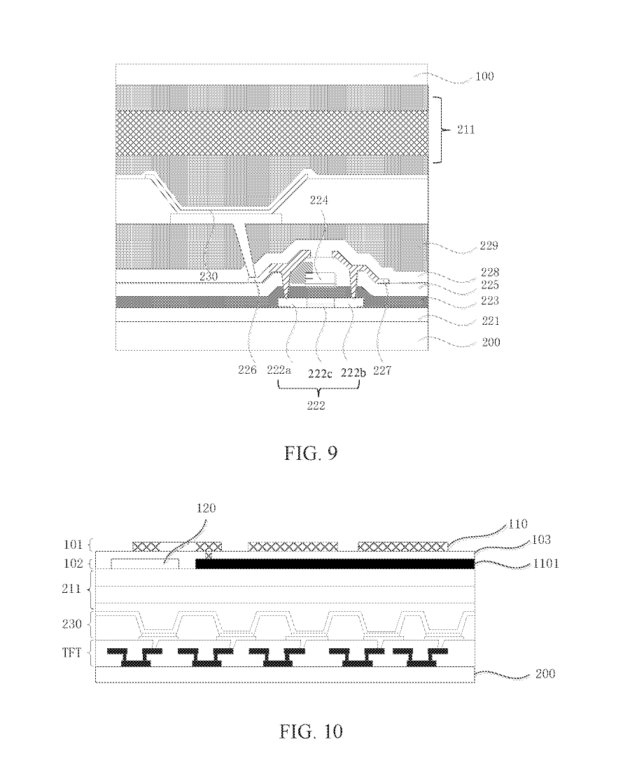

The embodiments of the present disclosure further provide a touch display panel including the touch sensor described above. FIG. 9 is a schematic diagram of a touch display panel provided by an embodiment of the present disclosure. As shown in FIG. 9, the touch display panel includes a substrate, a thin film transistor array disposed on the substrate, a light-emitting layer, and an encapsulation layer. The touch sensor is formed at a surface of the encapsulation layer.

With reference to FIG. 9, the touch display panel provided by an embodiment may be an organic light-emitting diode display panel. The touch display panel includes a substrate 200, which may be a flexible substrate. The flexible substrate may be made of any suitable insulation material having flexibility. For example, the flexible substrate may be made of material such as polyimide (PI), polycarbonate (PC), polyethersulfone (PES), polyethylene terephthalate (PET), polyethylene naphthalate (PEN), polyarylate (PAR), or glass fiber reinforce plastic (FRP), etc. The flexible substrate may be transparent, semitransparent or non-transparent. The flexible substrate makes the touch display panel to display in a bendable, curly and foldable state.

A buffer layer 221 is disposed on the flexible substrate, and the buffer layer 221 may cover the entire upper surface of the flexible substrate. In an embodiment, the buffer layer includes an inorganic layer or an organic layer. For example, the buffer layer may be made of material selected from inorganic material such as silicon oxide (SiOx), silicon nitride (SiNx), silicon oxynitride (SiOxNy), aluminum oxide (AlOx), aluminum nitride (AlNx) etc., or selected from organic material such as acryl, polyimide (PI), polyester etc. The buffer layer 221 may include a single layer or a plurality of layers. The buffer layer blocks oxygen and moisture, prevents moisture or impurities from diffusing via the flexible substrate, and provides a flat surface for a subsequent filmformed on this buffer layer.

The thin film transistor array includes a plurality of thin film transistors (TFT). The thin film transistors are disposed in the buffer layer 221. In an embodiment of the present disclosure, the structure with the top-gate type thin film transistor TFT will be described as an example.

The thin film transistor TFT includes a semiconductor active layer 222 disposed on the buffer layer 221. The semiconductor active layer 222 includes a source area 222a and a drain area 222b formed by doping N-type impurity ions or P-type impurity ions. An area between the source area 222a and the drain area 222b is a channel area 222c in which impurity is not doped.

The semiconductor active layer 222 may be formed by changing amorphous silicon to polycrystalline silicon by crystallization of amorphous silicon.

In order to crystallize the amorphous silicon, the amorphous silicon can be crystallized using a method such as rapid thermal annealing (RTA), solid phase crystallization (SPC), excimer laser annealing (ELA), metal induced crystallization (MIC) or sequential lateral solidification (SLS).

A gate insulation layer 223 includes an inorganic layer such as silicon oxide, silicon nitride, or metal oxide, and may include a single layer or a plurality of layers.

A gate electrode 224 is disposed in a specific area on the gate insulation layer 223. The gate electrode 224 may include a single layer or a plurality of layers of metal such as Au, Ag, Cu, Ni, Pt, Pd, Al, Mo, Cr, or alloy such as Al—Nd alloy, Mo—W alloy.

An interlayer insulation layer 225 is disposed on the gate electrode 224. The interlayer insulation layer 225 may be formed by an insulation inorganic layer such as silicon oxide or silicon nitride, etc. In one embodiment, the interlayer insulation layer may be formed. by an insulation organic layer.

The source electrode 226 and the drain electrode 227 are disposed on the interlayer insulation layer 225. The source electrode 226 and the drain electrode 227 are respectively electrically connected (or combined) to the source electrode area and the drain electrode area via a contact hole, and the contact hole is formed by selectively removing the gate insulation layer and the interlayer insulation layer.

A passivation layer 228 is disposed on the source electrode and drain electrode. The passivation layer 228 may be formed by an inorganic layer such as silicon oxide or silicon nitride, etc., or be formed by an organic layer.

A planarization layer 229 is disposed on the passivation layer 228. The planarization layer 229 includes an organic layer such as acryl, polyimide (PI) or benzocyclobutene (BCB), and the planarization layer 229 has a planarization function.

A light-emitting layer 230 is formed on the thin film transistor TFT.

An encapsulation layer 211 is disposed on the light-emitting layer 230. In an embodiment, the encapsulation layer 211 protects the light-emitting layer and other thin layers from being influenced by external moisture and oxygen, etc. The encapsulation layer 211 may be a thin film encapsulation layer including at least one organic layer and at least two inorganic layers, and the organic layer is disposed between two inorganic layers.

In an embodiment of the present disclosure, the touch sensor 100 may be fitted with the thin film encapsulation layer using a glue layer; or the thin film encapsulation layer is attached with a barrier film, and the touch sensor is fitted with the barrier film via a glue layer; or the thin film encapsulation layer is fitted with a circular polaroid, and the touch sensor is fitted with the circular polaroid; or it is also possible to make the touch sensor to be directly formed at the surface of the film encapsulation layer.

FIG. 10 is a schematic diagram of another touch display panel provided by an embodiment of the present disclosure. As shown in FIG. 10, the touch display panel includes a substrate 200, and also includes a thin film transistor array, a light-emitting layer 230 and an encapsulation layer 211 sequentially disposed on the substrate 200, and the touch sensor is disposed at a side of the encapsulation layer 211 away from the light-emitting layer 230. The touch sensor includes a first conductive layer 101, a second conductive layer 102, and an insulation layer 103 disposed between the first conductive layer and the second conductive layer. The first conductive layer includes a plurality of first electrodes 110, and the second conductive layer includes a plurality of second electrodes 120. A first leading wire 1101 is disposed in the second conductive layer, the second leading wire 1201 is electrically connected with one end of the second electrode, and the second conductive layer is also disposed in the second conductive layer. In an embodiment, the second conductive layer is disposed at a side of the insulation layer 103 close to the encapsulation layer 211. With this arrangement, both the first leading wire and the second leading wire are disposed at a side of the insulation layer 103 close to the light-emitting layer 230. The insulation layer 103 can achieve a certain protection effect on the first leading wire and the second leading wire, thereby preventing corrosion of the first leading wire and the second leading wire.

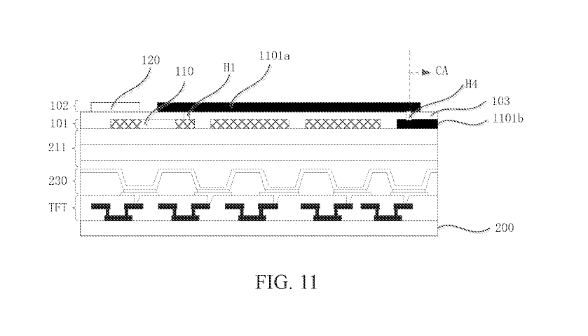

FIG. 11 is a schematic diagram of still another touch display panel provided by an embodiment of the present disclosure. As shown in FIG. 11, the touch display panel includes a substrate 200, and also includes a thin film transistor array, a light emitting layer 230, and an encapsulation layer 211 sequentially disposed on the substrate 200. The touch sensor is disposed at a side of the encapsulation layer 211 away from the light-emitting layer 230. The touch sensor includes a first conductive layer 101, a second conductive layer 102, and an insulation layer 103 disposed between the first conductive layer and the second conductive layer. The first conductive layer is at a side of the insulation layer 103 close to the encapsulation layer 211. A first leading wire 1101 includes a first section 1101a and a second section 1101b. The first section 1101a is disposed in the touch detection area and the second section 1101b is disposed in the peripheral area. The first conductive layer includes a plurality of first electrodes 110, a second leading wire 1201, and the second section 1101b of the first leading wire. The second conductive layer includes a plurality of second electrodes 120 and the first section 1101a of the first leading wire. The second leading wire 1201 is electrically connected with the second electrode 120 via a fourth through hole H4 at an end of the second electrode 120. One end of the first section 1101a of the first leading wire is electrically connected with the first electrode 110 via the first through hole H1, and the other end of the first segment 1101a. of the first leading wire is electrically connected with the second section of the first leading wire via the fourth through hole H4 at an end of the touch detection area close to the bonding pin. The second section 1101b of the first leading wire is connected with the bonding pin 104, and the second leading wire is electrically connected with the bonding pin 104.

In an embodiment, the first conductive layer is disposed at one side of the insulation layer 103 close to the encapsulation layer 211. Both the second section 1101b of the first leading wire and the second leading wire are disposed in the peripheral area and disposed in the first conductive layer, in this case, the insulation layer 103 can achieve a protection effect on the second section of the first leading wire and the second leading wire in the peripheral area, thereby preventing corrosion of the second section of the first leading wire and the second leading wire.

It should be noted that, the above description is merely the preferred embodiment and technical principles of the present disclosure. Those skilled in the art should understand that, the present disclosure is not limited to the embodiments herein, and various obvious changes, modifications and substitutions may be made by those skilled in the art without departing from the protection scope of the present disclosure. Therefore, although the present disclosure has been described in detail by way of the above embodiment, the present disclosure is not limited to the above embodiment, more other equivalent embodiments may be included by the present disclosure without departing from the concept of the present disclosure, and the scope of the present disclosure is determined by the scope of the appended claims.

What is claimed is:

1. A touch sensor, the touch sensor has a touch detection area and a peripheral area, and the touch sensor comprises:
a first conductive layer comprising a plurality of first electrodes extending in a first direction;
a second conductive layer comprising a plurality of first leading wires;
an insulation layer disposed between the first conductive layer and the second conductive layer;
a plurality of second electrodes extending in a second direction, the second electrodes being disposed in the first conductive layer or the second conductive layer, the first electrodes being insulated from the second electrodes;
a plurality of bonding pins disposed in the peripheral area external to a side of the touch detection area in the second direction;
a plurality of second leading wires;
wherein an angle is formed between the first direction and the second direction, which is neither equal to 0 degree nor equal to 180 degrees; each first leading wire has two ends, one end of each first leading wire is electrically connected with a respective one of the plurality of first electrodes, and the other end of each first leading wire is electrically connected with a respective one of the plurality of bonding pins, one end of each second leading wire is electrically connected with a respective one of the plurality of second electrodes, and the other end of each second leading wire is electrically connected with a respective one of the plurality of bonding pins; the insulation layer comprises a plurality of first through holes, and each first leading wire is electrically connected with the respective first electrode via a respective one of the plurality of first through holes; wherein the plurality of first leading wires and the plurality of second leading wires are led out from a side of the touch detection area closest to the bonding pin.

2. The touch sensor according to claim 1, wherein
the plurality of second electrodes is disposed in the second conductive layer, and each of the plurality of first leading wires is disposed between adjacent two of the plurality of second electrodes.

3. The touch sensor according to claim 2, wherein
a portion of each of the plurality of first leading wires disposed in the touch detection area has the same material as the plurality of second electrodes.

4. The touch sensor according to claim 3, wherein
a material of both the first conductive layer and the second conductive layer is metal mesh.

5. The touch sensor according to claim 2, wherein
a dummy electrode is disposed between adjacent two of the plurality of second electrodes, and the dummy electrode is connected to no leading wire and has a floating potential.

6. The touch sensor according to claim 5, wherein
the dummy electrode is provided between a portion of each of the plurality of first leading wires disposed in the touch detection area and a respective one of the plurality of second electrodes adjacent to a respective one of the plurality of first leading wires.

7. The touch sensor according to claim 2, wherein
a dummy electrode is disposed between adjacent two of the plurality of first electrodes.

8. The touch sensor according to claim 1, wherein
the plurality of second electrodes is disposed in the first conductive layer, each of the plurality of second electrodes comprises a plurality of second sub-electrodes, a bridging metal is provided between any adjacent two of the plurality of second sub-electrodes, and each bridging metal is disposed in the second conductive layer;
the insulation layer has a plurality of second through holes, and each bridging metal electrically connects adjacent two of the plurality of second sub-electrodes to one another via a respective two of the plurality of second through holes.

9. The touch sensor according to claim 8, wherein
each of the plurality of first leading wires is disposed between the bridging metals of a respective adjacent two of the plurality of second electrodes.

10. The touch sensor according to claim 9, wherein
each of the plurality of first leading wires comprises a first section and a second section;
the first section is disposed in the touch detection area and disposed in the second conductive layer;
the second section is disposed in the peripheral area and is disposed in the first conductive layer,
the first section is electrically connected to the second section via a third through hole of the insulation layer, and the third through hole is disposed at an end of the touch detection area close to the plurality of bonding pins.

11. The touch sensor according to claim 1, wherein
a portion of each of the plurality of first leading wires disposed in the touch detection area extends along the second direction.

12. The touch sensor according to claim 1, wherein
the first direction is perpendicular to the second direction.

13. The touch sensor according to claim 1, wherein
each of the plurality of first electrodes and each of the plurality of second electrodes are respectively a touch drive electrode and a touch detection electrode in a mutual-capacitance touch detection mode.

14. A touch display panel comprising a touch sensor, the touch sensor has a touch detection area and a peripheral area, wherein the touch sensor comprises:
a first conductive layer comprising a plurality of first electrodes extending in a first direction;
a second conductive layer comprising a plurality of first leading wires;
an insulation layer disposed between the first conductive layer and the second conductive layer;
a plurality of second electrodes extending in a second direction, the second electrodes being disposed in the first conductive layer or the second conductive layer, the first electrodes being insulated from the second electrodes;
a plurality of bonding pins disposed in the peripheral area external to a side of the touch detection area in the second direction;
a plurality of second leading wires;
wherein an angle is formed between the first direction and the second direction, which is neither equal to 0 degree nor equal to 180 degrees; each first leading wire has two ends, one end of each first leading wire is electrically connected with a respective one of the plurality of first electrodes, and the other end of each first leading wire is electrically connected with a respective one of the plurality of bonding pins, one end of each second leading wire is electrically connected with a respective one of the plurality of second electrodes, and the other end of each second leading wire is electrically connected with a respective one of the plurality of bonding pins; the insulation layer comprises a plurality of first through holes, and each first leading wire is electrically connected with the respective first electrode via a respective one of the plurality of first through holes; wherein the plurality of first leading wires and the plurality of second leading wires are led out from a side of the touch detection area closest to the bonding pin.

15. The touch display panel according to claim 14, comprising:
a substrate and
a thin film transistor array, a light-emitting layer and an encapsulation layer sequentially disposed on the substrate;
wherein the touch sensor is formed at a side of the encapsulation layer away from the light-emitting layer.

16. The touch display panel according to claim 15, wherein
the plurality of second electrodes and the plurality of second leading wires are disposed in the second conductive layer, and the second conductive layer is disposed at a side of the insulation layer closest to the encapsulation layer.

17. The touch display panel according to claim 15, wherein
the plurality of second electrodes is disposed in the second conductive layer, and the plurality of second leading wires is disposed in the first conductive layer;
each of the plurality of first leading wires comprises a first section and a second section, the first section is disposed in the touch detection area and the second section is disposed in the peripheral area, the first section is disposed in the second conductive layer and the second section is disposed in the first conductive layer;
the insulation layer has a plurality of fourth through holes, each of the plurality of second leading wires is electrically connected to a respective one of the plurality of second electrodes via a respective one of the plurality of fourth through holes, the first section of each of the plurality of first leading wires is electrically connected to the second section of the first leading wire via a respective one of the plurality of fourth through holes; and
the first conductive layer is disposed at a side of the insulation layer close to the encapsulation layer.
